(19) United States
(12) Patent Application Publication
(10) Pub. No.: US 2005/0264312 A1
(43) Pub. Date: Dec. 1, 2005

(54) Test device for electrical testing of a unit under test, as well as a method for production of a test drive

(75) Inventors: Gunther Bohm, Nufringen (DE); Michael Holocher, Rottenburg (DE)

Correspondence Address: OSTROLENK FABER GERB & SOFFEN, 1180 AVENUE OF THE AMERICAS, NEW YORK, NY, 100368403, US

(73) Assignee: Feinmetall GmbH

(21) Appl. No.: 11/102,255

(22) Filed: Apr. 8, 2005

(30) Foreign Application Priority Data
May 28, 2004 (DE) 10 2004027886.5

(51) Int. Cl. G01R 31/02

(52) U.S. Cl. 324/761

(57) ABSTRACT

The invention relates to a test device for electrical testing of a unit under test, in particular for the testing of wafers, having a contact head which can be associated with the unit under test and is provided with contact elements which are in the form of pins and form a contact pin arrangement, and having an electrical connecting apparatus, which has contact surfaces which make a touching contact with those ends of the contact elements which face away from the test plane accommodating the unit under test. The invention provides that the contact surfaces are on axial contact elements which extend in the axial direction and are in the form of mechanically processed contact surfaces.

### BACKGROUND OF THE INVENTION

The invention relates to a test device for electrical testing of a unit under test, in particular for the testing of wafers. The test device has a contact head which can be associated with the unit under test and is provided with contact elements which are in the form of pins and form a contact pin arrangement, and has an electrical connecting apparatus, which has contact surfaces which make a touching contact with those ends of the contact elements which face away from the test plane accommodating the unit under test.

The electrical test devices of the type mentioned initially are used to make electrical contact with a unit under test in order to test its functionality and serviceability.

The electrical test device produces electrical connections to the unit under test, that it makes contact on the one hand with electrical connections on the unit under test and on the other hand provides electrical contacts which are connected to a test system which supplies electrical signals to the unit under test via the test device in order to carry out, for example, resistance measurements, current and voltage measurements and so on for functional testing. Since the electrical units under test are often very small electronic components, for example electronic circuits on a wafer from which electronic components are manufactured. The contact elements, which are in the form of pins, on the test head have extremely small dimensions. In order now to provide a connection capability to the test system that has been mentioned, the contact elements of the test head make a touching contact with a connecting apparatus which provides conversion to a greater contact separation and to this extent allows the connection of electrical connecting cables which lead to the test system. During testing, the unit under test is located on the test plane, and the test device is lowered axially, preferably in the vertical direction, onto the unit under test. The first ends of the contact elements, which are in the form of pins, make contact with the unit under test. The other ends of the contact elements, which are in the form of pins, meet the contact surfaces of the connecting apparatus. Manufacturing tolerances and external conditions mean that this does not always ensure that the contact pins in the contact pin arrangement make contact with the unit under test with the same contact pressure, because even a minor discrepancy from the planar condition of a component can lead to a specific proportion of the contact pins or only one individual contact pin making contact at an early stage during the lowering of the unit under test, or else making contact only when all or many of the other contact pins have already made contact, in which case certain contact pins may have a greater or lesser contact pressure during testing, as well. In the worst case, it is possible in the case of the known test device for certain contact pins to make no contact with the unit under test, even though other contact pins are resting against the unit under test with the desired contact pressure. The contact pins preferably themselves compensate for minor discrepancies since they are resilient in the longitudinal direction, and are preferably in the form of bent wires. Bent wires have force applied to them in the longitudinal direction when making contact, and in this case bend elastically slightly in the form of an arc. However, this compensation is not always sufficient. The invention is therefore based on the object of providing a test device of the type mentioned initially in which reliable contact with the unit under test is always ensured.

### SUMMARY OF THE INVENTION

According to the invention, this object is achieved in that the contact surfaces are axial contact elements which extend in the axial direction and are in the form of mechanically processed contact surfaces. The mechanical processing is based, in particular, on grinding, milling and/or planing. All other known mechanical processing procedures which remove material may, of course, also be used. The contact surfaces are accordingly located on axial contact elements, that is intrinsically on components which extend in the axial direction. By way of example, these components may be in the form of axial contact pillars or axial contact raised areas. These axial contact elements may, for example, be milled or ground in order to produce the contact surfaces, in order to produce a defined axial position for the contact surface. This allows the axial position of the contact surface to be produced with high precision so that, in conjunction with the contact elements, reliable contact is always made with the unit under test, since the axial position of the contact surface can be produced on the basis of the procedure according to the invention in such a way that excessive contact pressure, weak contact pressure or even no contact pressure do not occur.

In particular, it is possible to provide for the contact surfaces each to be produced in their own right by mechanical processing, or to be in the form of contact surfaces produced by means of a single mechanical processing procedure. In consequence, according to the second alternative, all the contact surfaces of the connecting apparatus are produced jointly by means of a single mechanical processing procedure. This makes it possible, for example, to achieve an exact common plane or else arrangements with a deliberate discrepancy from the plane (an intrinsically planar inclined surface).

It is advantageous if the contact surfaces are each in the form of contact surfaces which are mechanically processed to be planar in their own right and also with respect to one another. This means that a perfect planar condition of the overall arrangement is achieved, offering the precondition for reliable contact. If the contact elements of the contact pin arrangement are likewise preferably produced jointly by means of a (different) mechanical processing procedure, for example a grinding procedure, with the same length and have thus been ground to be planar as an overall arrangement, an appropriately planar-ground connecting apparatus interacts perfectly with these contact elements, so that no major tolerance discrepancies occur in the axial direction which could endanger reliable contact.

The axial contact elements can be produced by applying material to basic contacts of the connecting apparatus. This may be done, for example, by applying solder to the basic contacts and by soldering to them, thus resulting in corresponding raised solder areas. These raised solder areas are then ground in order to produce the contact surfaces in the desired axial position. Alternatively, by way of example, it is possible to produce axial contact elements by, for example, soldering, welding or adhesively bonding (by means of electrically conductive adhesive) conductive bodies to the basic contacts, and then carrying out mechanical processing, for example, grinding, on the conductive bodies. For example, tiny conductive bodies in the form of pillars may be used, and are electrically conductively attached to the basic contacts.

In particular, it is possible to provide for the connecting apparatus to have a printed circuit board, in particular a multilayer printed circuit board. The printed circuit board has the basic contacts that have been mentioned on one face, which lead via conductor tracks to radially external connecting contacts, to which the electrical connecting cables which lead to the test system are connected. When using a printed circuit board as the connecting apparatus, plated-through holes are preferably used as the raised contact areas, that is the axial contact elements are formed by plated-through holes in the printed circuit board. The multilayer printed circuit board preferably has an outer layer which is associated with the contact head and has the plated-through holes. If the entire outer layer, that is the surface of this outer layer, of the printed circuit board is mechanically processed, then not only is the insulating material of the printed circuit board appropriately processed, but the plated-through holes located there as well, which to this extent can be positioned at the desired axial plane by the processing. The plated-through holes may have metallized walls and thus form annular contact surfaces facing the contact pins of the contact pin arrangement. If the contact pins are designed to have larger diameters than the free internal diameter of an annular contact arrangement such as this, there is no need to be concerned about ingress of a contact pin. However, provided that large-volume plated-through holes are used, this results in intrinsically closed contact surfaces, which improve the contact reliability.

The invention furthermore relates to a method for production of a test device, in particular according to one or more of the preceding explanations, in which the contact surfaces of the connecting apparatus are produced by mechanical processing, in particular by mechanical planar processing. In particular, the contact surfaces are produced by first of all applying a covering of conductive material, which is then mechanically processed.

Other features and advantages of the present invention will become apparent from the following description of the invention which refers to the accompanying drawings.

### BRIEF DESCRIPTION OF THE DRAWINGS

The drawings illustrate the invention with reference to exemplary embodiments, in which:

FIG. 1 shows a schematic cross-sectional view through an electrical test device,

FIG. 2 shows a detailed view of the test device shown in FIG. 1,

FIG. 3 shows a detailed view of a further exemplary embodiment of a test device,

FIG. 4 shows a detailed view of a further exemplary embodiment of a test device, and

FIG. 5 shows a detailed view of a further exemplary embodiment of a test device.

### DESCRIPTION OF PREFERRED EMBODIMENTS

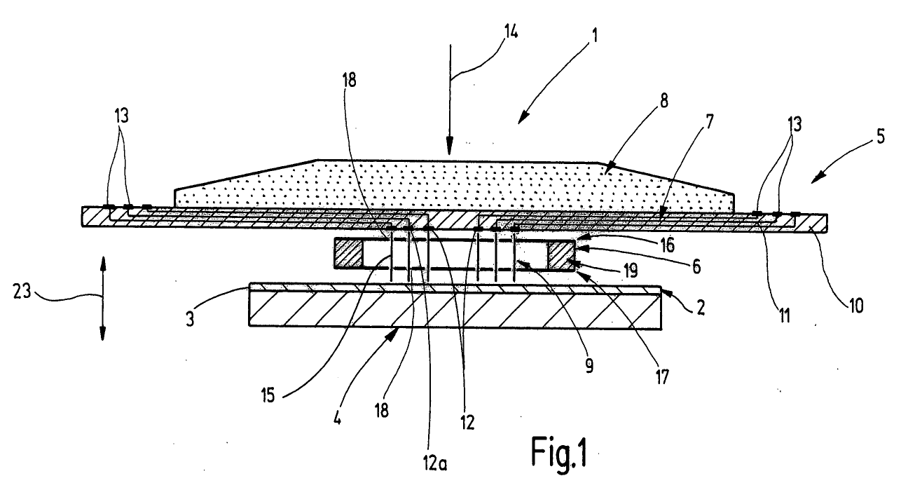

FIG. 1 shows a schematic illustration of a cross section through an electrical test device 1 which can be connected to a test system (which is not illustrated) by means of an electrical cable connection (which is not illustrated) in order to make contact with a unit under test 2, in order to subject the unit under test 2 to an electrical test. The unit under test 2 which, for example, is in the form of a wafer 3, is located on a supporting mount 4, which is referred to as a chuck and can be cooled or heated. This makes it possible to subject the unit under test 2 to different temperatures during the electrical testing, for example in the range from minus 50° C. to plus 200° C., in order to test whether it operates correctly in this temperature range.

A vertical test card 5 which forms the test device 1 is provided in order to make contact with corresponding connecting points on the wafer 3.

The test device 1 has a contact head 6 and a connecting apparatus 7. The connecting apparatus 7 is supported on a supporting apparatus 8. The contact head 6 is provided with a large number of contact elements 9 which are mounted such that they can move longitudinally, with one of their end areas being associated with the unit under test 2, and their other end areas being associated with the connecting apparatus 7. The connecting apparatus 7 is in the form of a multilayer printed circuit board 10 with conductor tracks 11, with the conductor tracks 11 having basic contacts 12a of contacts 12 at their ends associated with the contact head 6. The basic contacts 12a are associated with the respective contact elements 9. The conductor tracks 11 have, at their radially outer ends, electrical connecting surfaces 13, which can be connected to the test system (which is likewise not illustrated) via cable connections (not illustrated). The arrangement is designed such that the connecting apparatus 7 forms a conversion apparatus, that is the very short distance between the tiny small basic contact surfaces 12b of the basic contacts 12a (with a diameter, for example, of 50 to 300 μm) is converted via the conductor tracks 11 to greater distances between the connecting surfaces 13. Furthermore, the connecting surfaces 13 are each of a size to allow the cable connections to the test system to be produced.

During the testing of the unit under test 2, the test device 1 is moved in the axial direction (arrow 14) towards the unit under test 2, with the printed circuit board 10 being supported by the supporting apparatus 8. The ends of the contact elements 9 meet the wafer 3 on the one hand and the contacts 12 on the other hand. Since the contact elements 9 are in the form of bent wires 15, that is they are designed to be slightly resilient by bending in the axial direction, this allows correct contact to be made provided that, assuming that the wafer 3 is planar and that all the bent wires 15 have the same length, the contact surfaces 12c of the contacts 12 are likewise located at the same height as one another, that is to say a planar condition likewise exists. The way in which this planar condition of the contacts 12 can be achieved is explained in more detail in the following text.

The contact head 6 has two parallel ceramic plates 16 and 17 which are separated from one another and are provided with respective bearing holes 18 for holding the bent wires 15. The parallel spacing between the two ceramic plates 16 and 17 is achieved by means of a spacer 19.

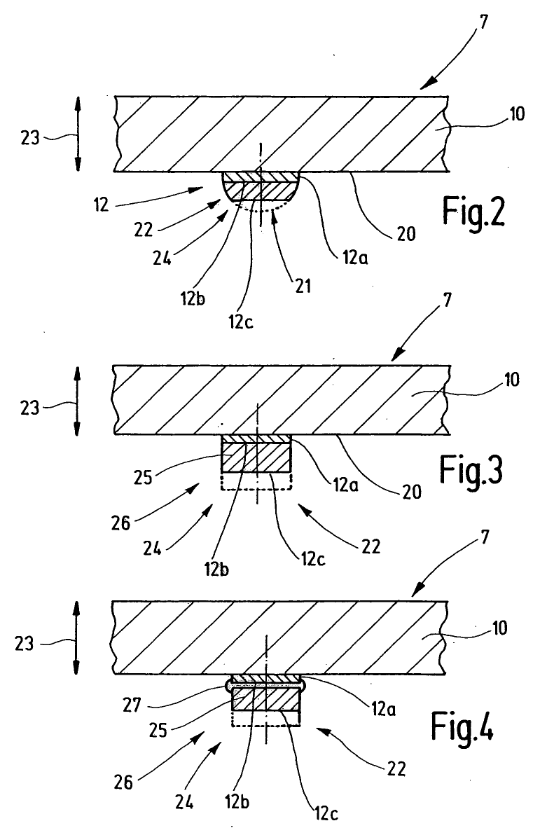

FIG. 2 shows an area of the test device 1, particularly a section of the connecting apparatus 7. The contacts 12, of which one is illustrated in FIG. 2, are located on the lower face 20 of the printed circuit board 10. Each contact 12 comprises the basic contact 12a, which is in the form of a conductor track pad, and is connected to a corresponding conductor track, although this is not illustrated in FIG. 2. A raised solder area 21 is applied to the basic contact surface 12b of the basic contact 12a. The raised solder area 21 is comprised of a solder material, for example in the form of a solder tin ball, which has been melted on so that a raised area “in the form of a hump” is formed on the basic contact 12a. In FIG. 2, this raised solder area 21 is illustrated by a dashed line in the lower central area, in order to show its original shape. Since there are a large number of basic contacts 12a on the lower face 20 of the printed circuit board 10 and a corresponding raised solder area 21 is applied to each basic contact 12a, this produces a large number of axial contact elements 22. This is in each case intended to mean the entire contact 12. Since the contact 12 extends in the axial direction (double-headed arrow 23) in FIG. 1 and FIG. 2, this results in a contact element which is formed appropriately in the axial direction and leads to the chosen designation “axial contact element”.

Since the individual axial contact elements 22 result in corresponding tolerance dimensions in the axial direction owing to the solder tin balls melted onto each of them, all of the axial contact elements 22 are processed to be planar at their lower ends 24 during the production process by means of a common mechanical processing procedure, in particular a precision milling procedure and/or precision grinding procedure, in particular by being milled and/or ground. In each case, this forms a contact surface 12c, in particular a milled and/or ground contact surface 12c, on each axial contact element 22. All of the contact surfaces 12c are intrinsically planar as a result of the milling procedure and/or grinding procedure, are also planar with respect to one another, and are additionally planar with respect to the upper face of the mount 4, and are thus planar with respect to the unit under test 2 which, for example, is in the form of a wafer 3. During their production, the bent wires 15 are likewise all changed to the same length by means of a mechanical processing procedure, in particular likewise by means of a milling procedure and/or a grinding procedure. This produces overall an exactly planar test device 1, which ensures, when contact is made for a unit under test 2, that there are no “leading” or “lagging” contacts when the test device 1 is lowered onto the unit under test 2, and that all of the contact elements 9 make contact with the corresponding test points on the unit under test with at least essentially the same contact pressure.

FIG. 3 shows a further exemplary embodiment of a test device 1, in which, in contrast to the exemplary embodiment shown in FIG. 2, the respective contact 12 is produced on the lower face 20 of the connecting apparatus 7 or of the printed circuit board 10, by attaching a conductive body 25 to the basic contact 12a. This is preferably done by welding the corresponding end face of the conductive body to the basic contact surface 12b. The conductive body 25 may, for example, be a tiny cylindrical, electrically conductive contact part. This produces conductive body raised areas 26 on the lower face 20 of the printed circuit board 10, which in order to achieve a planar arrangement, are processed in the area of their free ends 24 in the course of a joint mechanical processing procedure. This results, for example, in milled and/or ground contact surfaces 12c. The removed material area is indicated by means of the dotted line in FIG. 3.

FIG. 4 shows an exemplary embodiment of a test device 1 which is provided with axial contact elements 22 and corresponds to the exemplary embodiment shown in FIG. 3. The only difference is that the conductive body 25 is attached to the basic contact 12a by soldering rather than by welding. The soldered joint 27 can be seen in FIG. 4. Otherwise, in the same way as in the case of the exemplary embodiments in the previous figures, a mechanical precision processing procedure is carried out in order to produce the planar contact surfaces 12c.

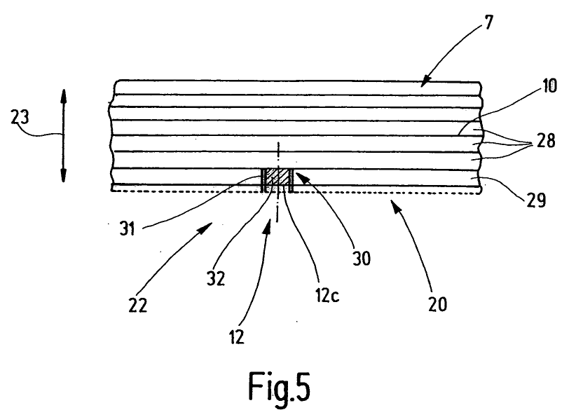

In the exemplary embodiment shown in FIG. 5, the respective axial contact element 22 which extends in the axial direction is created by the connecting apparatus 7 which is in the form of a multilayer printed circuit board 10, which has a corresponding number of layers 28 with associated conductor tracks (which are not illustrated), with the lowermost layer 29 having a plated-through hole 30 in order to create the respective axial contact element 22. This means that the layer 29 has an axial hole 31 whose entire volume is preferably filled with conductive material 32, which is connected to a corresponding conductor track, that is not illustrated. The entire lower face 20 of the printed circuit board 10 is preferably mechanically processed to be planar in a single operation in order to produce the planar contact surface 12c of each contact 12, so that both insulating material and material on the plated-through holes 30 are removed, producing a planar surface overall in which the mechanically processed contact surfaces 12c of the plated-through holes 30 are located, and with the plated-through holes each resulting in axial contact elements 22 which extend in the axial direction.

The procedure according to the invention, specifically the mechanical processing, in particular milling and/or grinding of raised contact areas which are preferably in the form of pillars, results in the production of processed contact surfaces 12c on the connecting apparatus 7, which are each intrinsically planar and are also in a planar position with respect to one another. The diameters of these mechanically processed contact surfaces 12c range between about 50 and 300 μm. The individual contact surfaces 12c, which are electrically isolated from one another, have, for example, distances between their centers of 100 to 300 μm. This distance between centers is, of course, dependent on the contact position of the respective unit under test 2 to be tested.

In particular, it is possible to provide for the raised contact areas mentioned above, for example raised solder areas or raised contact areas created by axial contact elements, to be embedded in an embedding compound, which is electrically non-conductive, before the mechanical processing, in particular before they are milled over or ground over. For example, this may be a plastic compound. The advantage is that the very sensitive raised contact areas are mechanically supported and thus protected to the best extent during the mechanical processing procedure, so that the raised areas are subject to only a very small amount of mechanical stress during the mechanical processing. It is thus possible, for example, to embed the raised areas in epoxy resin and then to carry out the mechanical processing process, after curing, with the supporting material that has been applied either being completely removed again during the mechanical processing, or else remaining in places on the product, depending on the extent to which the mechanical processing is carried out. Fundamentally, it should be noted that a large number of different embedding materials are suitable for the stated support function, with the embedding material in some cases being left on the workpiece, or else being removed again.

The invention is additionally distinguished in that, after the mechanical processing (independently of the respective exemplary embodiment), the surface of the contact surfaces is still covered with noble material, in order to create a robust surface with good electrical contact characteristics. For example, chemical or electrochemical gold plating may be carried out. Other metals may, of course, also be applied in order to achieve the desired effect. An embodiment such as this provides in particular for a raised area which is comprised of solder material, in particular solder tin, to be provided after mechanical processing with a layer structure composed of gold, nickel and gold again. The different materials are applied successively by electrochemical techniques.

It is also feasible for a surface layer of the type mentioned above which has been applied to the respective contact surface after the mechanical processing to be processed mechanically once again. This processing is carried out only to a minor extent in order not to completely remove the surface layer again.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

1. A test device for electrical testing of a unit under test comprising:
a contact head which can be associated with the unit under test contact elements on the contact head and which are in the form of pins that are arrayed to form a contact pin arrangement, and an electrical connecting apparatus, which contact surfaces which make a touching contact with first ends of the contact elements which face away from the test plane accommodating the unit under test,
the contact surfaces being on axial contact elements which extend in the axial direction and are in the form of mechanically processed contact surfaces.

2. The test device according to claim 1, wherein the contact surfaces are in a form to be produced by a single mechanical procedure.

3. The test device according to claim 1, wherein each contact surface is a form which has been mechanically processed to be planar and also with respect to one another.

4. The test device according claim 1, wherein the axial contact elements comprise solder raised areas.

5. The test device according to claim 1, wherein the axial contact elements are soldered or welded conductive bodies defining raised areas.

6. The test device according to claim 1, wherein the connecting apparatus includes a printed circuit board.

7. The test device according to claim 6, wherein the axial contact elements comprise plated-through holes in the printed circuit board.

8. The test device according to claim 7, wherein the printed circuit board is a multilayer printed circuit board, and the plated-through holes are located in an outer layer of the printed circuit board.

9. The test device according to claim 8, wherein the outer layer of the printed circuit board together with the plated-through holes has a mechanically processed surface.

10. The test device according to claim 8, wherein the plated-through holes are formed throughout the entire volume.

11. The test device according to claim 1, wherein the axial contact elements are embedded in an electrically non-conductive, curing embedding compound adopted for mechanical processing to then be carried out.

12. The test device according to claim 1, wherein an at least electrically conductive coating is applied to the contact surfaces after a mechanical processing.

13. The test device according to claim 12, wherein at least two coatings comprised of materials are applied successively to the contact surfaces.

14. Method for production of a test device, in particular according to one or more of the preceding claims, in which the contact surfaces of the connecting apparatus are produced by mechanical processing, in particular by mechanical planar processing.

15. Method according to claim l4, wherein a covering of conductive material is applied first of all in order to create the contact surfaces (12c) and is then mechanically processed.

16. The test device according to claim 6, wherein the circuit board is a multilayer printed circuit board.

17. The test device according to claim 10, wherein the holes are metallized throughout the entire volume of the board.
